(19) United States
(12) Patent Application Publication
(10) Pub. No.: US 2015/0316450 A1
(43) Pub. Date: Nov. 5, 2015

(54) Functional Testing Device for Used Electronics

(71) Applicant: Tu Nguyen, Fremont, CA (US)

(72) Inventor: Tu Nguyen, Fremont, CA (US)

(21) Appl. No.: 14/696,417

(22) Filed: Apr. 25, 2015

Related U.S. Application Data
(60) Provisional application No. 61/987,480, filed on May 1, 2014.

(51) Int. Cl. G01M 99/00; G01R 1/04; G01R 31/00; H04R 29/00

(52) U.S. Cl. CPC G01M 99/008; H04R 29/00; G01R 1/04; G01R 31/00

(57) ABSTRACT

A device and method for evaluating the functionality of an electronic device are provided. The functionality of the device may be evaluated manually, semi-automatically, or automatically.

### CROSS-REFERENCE TO RELATED APPLICATIONS

The present application takes priority from Provisional App. No. 61/987,480, filed May 1, 2014, which is herein incorporated by reference.

### STATEMENT REGARDING FEDERALLY SPONSORED RESEARCH AND DEVELOPMENT

Not applicable.

### BACKGROUND

1. Field of the Invention

The present invention relates generally to recycling electronic devices, and more particularly to a device that automatically tests the functionality of a used electronic device.

2. Description of the Related Art

Due to the rapid evolution of electronic devices, consumers often have an excess of old, unwanted electronic devices cluttering up their homes. Such devices may include cell phones, PDA's, smartphones, GPS devices, calculators, mp3 players, and other similar electronics. While such devices may be worth money, it is often complicated to sell the devices, and too many of them end up thrown away. When thrown away, these devices contaminate the waste stream, due to their heavy metal content. This is a serious hazard to the environment.

Many phone companies and other entities offer consumers the opportunity to test the functionality of their electronic device. However, it is often difficult to uncover functional problems with the device in the relatively brief time that such a testing process may take. On the other hand, a cursory evaluation may miss some significant problems with the device that may affect full functionality.

A need therefore exists for a system and method of quickly and comprehensively evaluating the functionality of an electronic device.

### SUMMARY OF THE INVENTION

The present invention is a functional testing device for used electronics, comprising an evaluation chamber that is appropriately sized for a used electronic device; a device holder located inside the chamber; at least one cable connector; a user interface, with a display and at least one input device, and a processor that is configured to connect to an electronic device, identify the electronic device, and test at least one function of the electronic device.

The functions tested by the device of the present invention can include the cellular transmitter and receiver, Bluetooth transmitter and receiver, display, headphones, speaker, microphone, buttons, touchscreen, motion sensor, compass, processor, wi-fi transmitter and receiver, PIN charge, GPS, infrared transmitter and receiver, fingerprint scanner, temperature sensor, gyroscope, light sensor, pulse sensor, and at least one camera.

In an embodiment, the tests are performed automatically without intervention by an operator. In another embodiment, the tests are performed semi-automatically with assistance from an operator.

The processor can also be configured to generate a report based on results of the functional tests. The report may also be transmitted to a server.

The device holder can comprise multiple interchangeable adapters for holding at least two different types of electronic device.

The functional testing device can comprise multiple cables for connecting to at least two different types of electronic device.

The functional testing device can also comprise a communication module that connects the functional testing device to a server.

The functional testing device can connect to a used electronic device wirelessly or by a cable.

The functional testing device can comprise various mechanical attachments for performing tests on the used electronic device, such as a mechanical finger for testing the touchscreen, a module for pushing the buttons, or a module for covering up the light sensor.

The method of the present invention comprises placing the used electronic device into an evaluation chamber, connecting it to a processor, and using the processor to identify the used electronic device, perform at least one functional test on the used electronic device, and generate a report on the results of the at least one functional test.

As above, the functional tests can include testing the cellular transmitter and receiver, Bluetooth transmitter and receiver, display, headphones, speaker, microphone, buttons, touchscreen, motion sensor, compass, processor, wi-fi transmitter and receiver, PIN charge, GPS, infrared transmitter and receiver, fingerprint scanner, temperature sensor, gyroscope, light sensor, pulse sensor, and at least one camera.

The functions to be tested may be selected by a user interface.

In an embodiment, an app may be installed on the electronic device, and may be used to perform at least one test. In another embodiment, at least one test is performed by the processor.

### LIST OF FIGURES

FIG. 1 shows a front view of an embodiment of the present invention.

FIG. 2 shows a rear view of an embodiment of the present invention.

FIG. 3 shows a view of an embodiment of the present invention with the door open and an iPad in the adapter.

FIG. 4 shows a view of an embodiment of the present invention with the door open and an iPad Mini in the adapter.

FIG. 5 shows a view of an embodiment of the present invention with the door open and an iPhone in the adapter.

FIG. 6 shows a view of an embodiment of the present invention with the door open and an iPhone in the adapter.

FIG. 7 shows a flowchart of the method of the present invention.

### DETAILED DESCRIPTION OF THE PREFERRED EMBODIMENT

An object of the present invention is to provide an easy way to conduct a comprehensive evaluation of the functionality of an electronic device. The electronic device in question can be any type of smartphone, cell phone, tablet, gaming device, mp3 player, or any other small electronic mobile device.

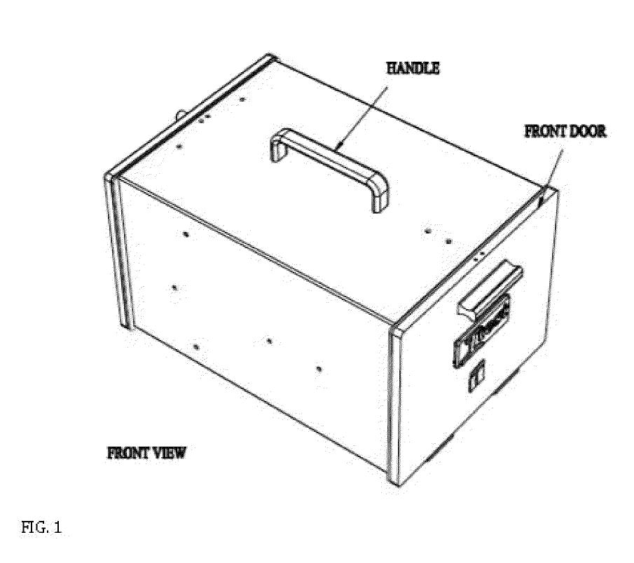

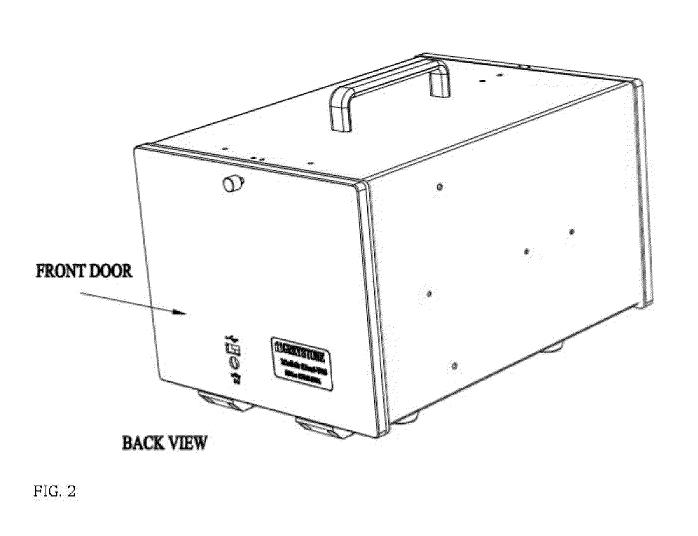

In its preferred embodiment, the system of the present invention comprises an acoustic lined and light insulated evaluation chamber appropriately sized for an electronic device to fit into it, a processor and memory, a device holder, at least one cable connector, and a user interface, preferably comprising a display and at least one input device. FIG. 1 shows one embodiment of the system of the present invention; FIG. 2 shows the back view.

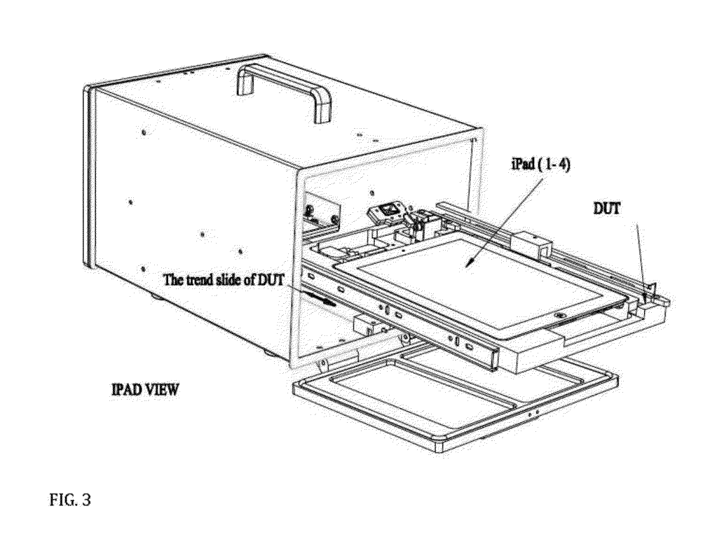

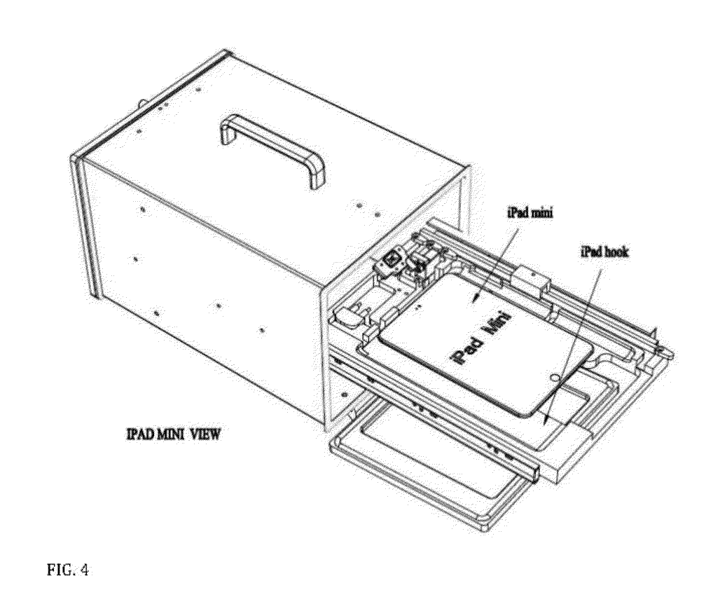

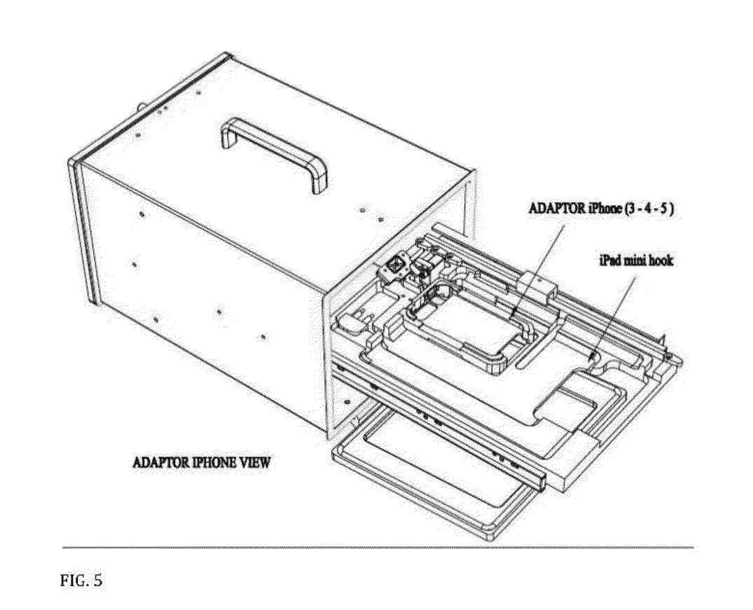

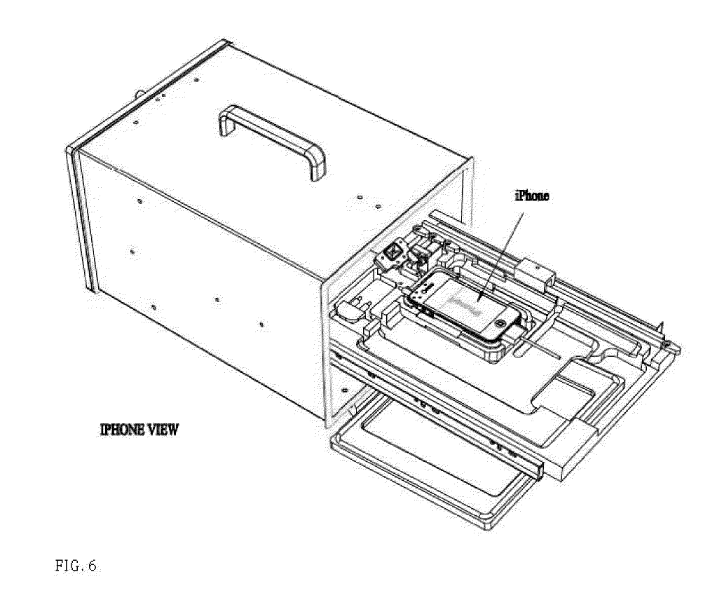

FIG. 3 shows the system of the present invention with the door open and the device holder, here comprising a tray, slid out with an electronic device on the tray. The tray is preferably large enough to support a standard-size tablet. As shown in FIGS. 4, 5, and 6, adapters can be fitted into the tray to support an iPad mini, an iPhone, or any other smartphone, small tablet, mp3 player, gaming device, and similar electronic devices.

The system and method of the present invention can test any function of a typical small electronic device. A non-limiting listing of functions includes: phone functionality, screen functionality (including any dead pixels), headphone, speaker, microphone, buttons, touchscreen, motion sensor, compass, Bluetooth, operating system, radio signal, wi-fi, 3G/4G, date/time, PIN charge, GPS, location service, remote control, fingerprint scanning, temperature, gyroscope, light sensor, pulse sensor, biometric sensors, camera, and so on. It will be understood that other functionalities of a small electronic device are also encompassed into the present invention and may also be tested this way. Tests can be executed through an application installed to the electronic device, through wireless connections, or through wired connections.

The testing can be manual, semi-automatic, or fully automatic. In manual testing, the user selects what functions of an electronic device to test and the system tests just those functions. For example, a user may wish to verify whether or not the wi-fi functions work, but not do any other testing.

In semi-automatic testing, the user is prompted to test various functions of the electronic device by messages appearing on the user interface. In fully automatic testing, the electronic device functions are tested one after the other, automatically without intervention from the user.

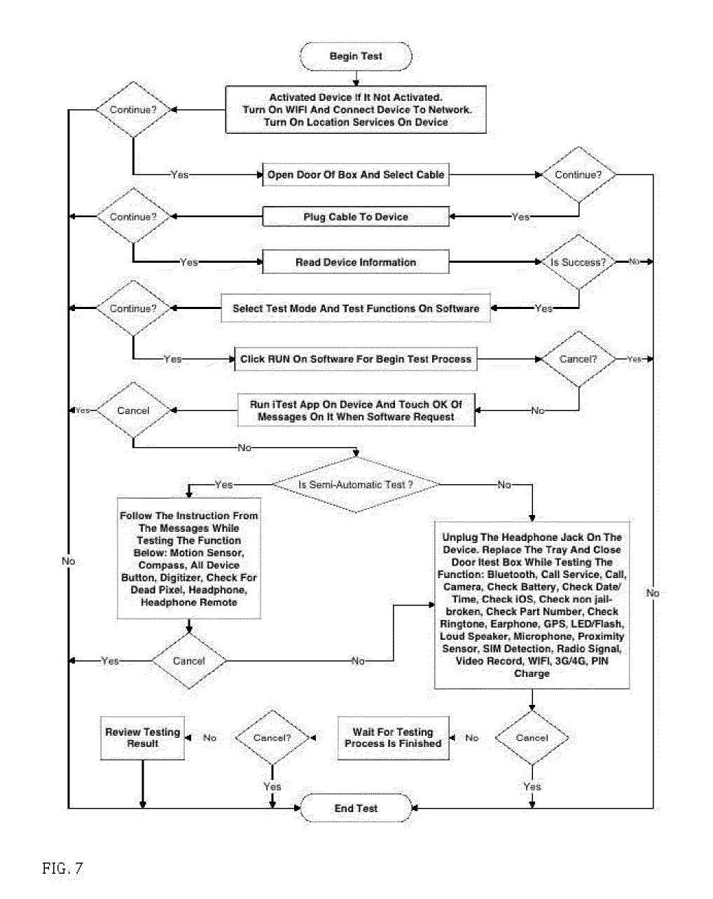

FIG. 7 shows a flowchart of the preferred embodiment of the method of evaluation of the present invention. As the test begins, the electronic device is activated if necessary; the wi-fi services and location services can be turned on, and the electronic device can be connected to the network. The user then opens the door of the system to put the electronic device in and connects the device to the system with the appropriate cable or wireless connection.

The system then reads the device information from the electronic device. Such information may include, but is not limited to, device ID, device type, operating system, and other information that can be read from an electronic device.

The user then is prompted to select the test mode and test functions on the user interface. The user may be able to select manual, semi-automatic, or automatic testing, or a combination of the three, or to select specific functions to be tested or the order in which they are tested. The user may also be able to install a special test app on the electronic device to be tested which can assist in the testing process.

If the user selects “semi-automatic test”, the user is then prompted to follow instructions while testing each function of the electronic device. For example, the user may be prompted to move the device around in order to test the motion sensor, turn it around in order to test the compass, or push various device buttons. In some embodiments, some functions of the device may only be tested in semi-automatic mode, since the system may be unable to move the device or push its buttons. In other embodiments, the system may have modules or attachments that can move the device, push its buttons, or activate its touchscreen, in order to provide automatic testing of these functions.

If the user selects “automatic test”, the user is then prompted to place the device onto the tray and close the door. The system then tests various functions of the electronic device automatically. Such functions may include, but are not limited to, Bluetooth, call service, call, camera, battery, date/time, iOS, jailbroken, part number, ringtone, earphone, GPS, LED/flash, speaker, microphone, proximity sensor, SIM detection, radio signal, video record, wi-fi, 3G/4G, finger scanner, gyroscope and PIN charge. In an embodiment, the system may be able to move the device or activate its buttons or touchscreen, and may also be able to test the motion sensor, compass, device buttons, digitizer, screen, headphones, and headphone remote. Those functions may be tested in any order, as desired by the user or as set at the factory.

The system can then provide a report on the testing results, summarize the testing results on the user interface, or output the testing results in some other way.

The system of the present invention also comprises a communication module that enables it to connect to a central server, whether to transmit data for evaluation, or to transmit its evaluation of the device, or to receive data of any kind.

Exemplary embodiments have been described above. It will, however, be clear to a person of reasonable skill that the invention encompasses other embodiments, which also fall into the scope of the present invention.

1. A functional testing device for used electronics, comprising:
an evaluation chamber, said evaluation chamber appropriately sized so that an electronic device may fit inside;
a device holder located inside the evaluation chamber, said device holder shaped in such a way that an electronic device may be securely held therein;
at least one cable connector;
a user interface, said user interface comprising:
a display;
at least one input device;
a processor, said processor configured to perform the following tasks:
connecting to an electronic device;
identifying the electronic device;
testing at least one function of the electronic device.

2. The functional testing device for used electronics of claim 1, where the processor is configured to test at least one function from the following group of functions:
cellular transmitter and receiver;
Bluetooth transmitter and receiver;
display;
headphones;
speaker;
microphone;
buttons;
touchscreen;
motion sensor;
compass;
processor;
wi-fi transmitter and receiver;
PIN charge;
GPS;
Infrared transmitter and receiver;
fingerprint scanner;
temperature sensor;
gyroscope;
light sensor;
pulse sensor;
at least one camera.

3. The functional testing device for used electronics of claim 1, wherein the processor is configured to perform functional tests automatically without intervention by an operator.

4. The functional testing device for used electronics of claim 1, wherein the processor is configured to perform functional tests semi-automatically with assistance from an operator.

5. The functional testing device for used electronics of claim 1, wherein the processor is further configured to generate a report based on results of the functional tests.

6. The functional testing device for used electronics of claim 1, wherein the device holder comprises at least two interchangeable adapters for holding at least two different types of electronic device.

7. The functional testing device for used electronics of claim 1, comprising at least two cables for connecting to at least two different types of electronic device.

8. The functional testing device for used electronics of claim 1, further comprising a communication module that connects the functional testing device to a server.

9. The functional testing device for used electronics of claim 8, wherein the processor is configured to generate a report based on results of the functional tests and transmit the report to a server.

10. The functional testing device for used electronics of claim 1, wherein the functional testing device connects to a used electronic device by a cable.

11. The functional testing device for used electronics of claim 1, wherein the functional testing device connects to a used electronic device wirelessly.

12. The functional testing device for used electronics of claim 1, further comprising a module for covering up the light sensor of the used electronic device.

13. The functional testing device for used electronics of claim 1, further comprising a mechanical finger for testing the touchscreen of the used electronic device.

14. The functional testing device for used electronics of claim 1, further comprising a module for pushing the buttons on the used electronic device.

15. A method for functional testing of a used electronic device, comprising:
placing the used electronic device into an evaluation chamber;
connecting the used electronic device to a processor;
using the processor to identify the used electronic device;
using the processor to perform at least one functional test on the electronic device;
using the processor to generate a report on the results of the at least one functional test on the electronic device.

16. The method of claim 15, wherein the at least one functional test tests at least one of the following functions:
cellular transmitter and receiver;
Bluetooth transmitter and receiver;
display;
headphones;
speaker;
microphone;
buttons;
touchscreen;
motion sensor;
compass;
processor;
wi-fi transmitter and receiver;
PIN charge;
GPS;
Infrared transmitter and receiver;
fingerprint scanner;
temperature sensor;
gyroscope;
light sensor;
pulse sensor;
at least one camera.

17. The method of claim 15, further comprising:
selecting at least one function to be tested via a user interface.

18. The method of claim 15, further comprising:
installing an app on the electronic device;
wherein the performing at least one test on the electronic device is done by the app.

19. The method of claim 15, wherein the performing at least one test on the electronic device is done by the processor.
